(19) United States
(12) Patent Application Publication
(10) Pub. No.: US 2019/0001360 A1
(43) Pub. Date: Jan. 3, 2019

(54) APPARATUS AND METHOD FOR AEROSOL DEPOSITION OF NANOPARTICLES ON A SUBSTRATE

(71) Applicant: National Research Council of Canada, Ottawa (CA)

(72) Inventors: Jacques LEFEBVRE, Gatineau (CA); Patrick MALENFANT, Orleans (CA)

(73) Assignee: National Research Council of Canada, Ottawa, ON (CA)

(21) Appl. No.: 15/748,947

(22) PCT Filed: Jun. 14, 2016
(86) PCT No.: PCT/IB2016/053502

§ 371 Date: Jan. 30, 2018

Related U.S. Application Data
(60) Provisional application No. 62/199,675, filed on Jul. 31, 2015.

(30) Foreign Application Priority Data
Jul. 31, 2015 (CA) 2,899,255

(51) Int. Cl. B05B 12/08; B05B 12/20; B05B 5/025; B05B 5/10; B05B 5/16; C01B 32/159; C08L 27/12; C08L 25/18; H01L 51/05; H01L 51/00

(52) U.S. Cl. CPC B05B 12/082; B05B 12/20; B05B 5/0255; B05B 5/10; B05B 5/165; B82Y 30/00; C08L 27/12; C08L 25/18; H01L 51/052; H01L 51/0048; C01B 32/159

(57) ABSTRACT

Provided is an apparatus for aerosol deposition of nanoparticles on a substrate. The apparatus includes: an aerosol generator for generating an aerosol of micron-sized droplets, each droplet having a limited number of nanoparticles; and a deposition chamber for receiving the aerosol from the aerosol generator. The deposition chamber having an electrostatic field for attracting droplets in the aerosol to the substrate. The electrostatic field being substantially perpendicular to the substrate. The apparatus allows for films/networks of nanoparticles to be patterned on the substrate to sub-millimeter feature sizes, which allows the fabrication of transistor devices for printable electronics applications. Also provided are methods for depositing nanoparticles on a substrate and materials having networks of such nanoparticles.

### CROSS-REFERENCE TO RELATED APPLICATIONS

This application claims priority to Canadian Patent Application 2,899,255 filed Jul. 31, 2015 and claims the benefit of U.S. Provisional Patent Application 62/199,675 filed Jul. 31, 2015, the entire contents of both of which are herein incorporated by reference.

### FIELD OF INVENTION

The invention is generally directed to printable electronics. More specifically, the invention is directed to an apparatus and method for aerosol deposition of nanoparticles on a substrate.

### BACKGROUND OF INVENTION

The low cost and flexibility of being able to use conventional printing methods and equipment to print electrical circuits on various surfaces including plastic rolls has expanded the potential environments where electronics are used.

Similar to traditional printing methods, printable electronics require depositing inks on a surface in a defined pattern. The inks used in printable electronics include functional electronic or optical materials, such as inks having carbon nanotubes, the material acting as a macroscopic transistor channel when printed to form a network.

Carbon nanotubes have outstanding electrical properties with semiconducting single-walled carbon nanotubes (SWCNTs) performing as semiconducting channels in high mobility transistors in printable electronics applications. In such applications, thousands of carbon nanotubes are laid down on a surface and form a network of electrically connected wires. These networks form readily upon soaking a substrate in a carbon nanotube containing solution (or ink). For several applications where the network should not cover an entire surface but be patterned to sub-millimetre feature sizes, a printing apparatus is required. Several technologies exist for the deposition of ink materials and they fall into essentially two categories: 1) serial, such as inkjet or aerosol jet; and 2) parallel, such as screen, gravure and flexo-printing. However, the majority of these systems are not adapted to ultrathin films (i.e. films that have a thickness of <10 nm) such as those used in the carbon nanotube network transistors.

Furthermore, the present systems require specific ink formulations, which are engineered to have physical parameters within a set window. However, additives introduced into such formulations can severely degrade electrical performance of transistor devices. In addition, deposited films are generally much thicker than needed for transistor operation. Therefore, there is a need for a deposition system that can be used to assemble carbon nanotubes and other types of nanoparticles into networks of thin film transistors.

### SUMMARY OF INVENTION

According to an aspect of the present invention, there is provided an apparatus for aerosol deposition of nanoparticles on a substrate. The apparatus includes: an aerosol generator for generating an aerosol of micron-sized droplets, each droplet comprising a limited number of nanoparticles; and a deposition chamber for receiving the aerosol from the aerosol generator. The deposition chamber has an electrostatic field for attracting individual droplets in the aerosol to a substrate. The electrostatic field is substantially perpendicular to the substrate.

In an embodiment, the apparatus also includes an injector nozzle with one to several openings either parallel or perpendicular to the deposition substrate.

In one embodiment, the deposition chamber further includes a stencil mask positioned between the flow of the aerosol and the substrate.

In a further embodiment, the electrostatic field is provided by interspaced charged plates and the substrate is positioned on the grounded plate.

In yet a further embodiment, the charged plates are electrostatically charged insulators or voltage biased conductors.

In a still further embodiment, the charged plates are patterned to spatially modulate the electric field and promote nanoparticle deposition at specific locations on the substrate.

In another embodiment, the aerosol flows in a laminar fashion and is spatially engineered to afford nanoparticle deposition at specific locations on the substrate.

According to another aspect of the invention, there is provided the use of the apparatus described above in the production of a thin film of nanoparticles.

In one embodiment, the apparatus is used in the production of a thin film transistor.

In another embodiment, the apparatus is used in the production of a conductive electrode, a diode, a photovoltaic cell, a physical sensor or chemical sensor. The conductive electrode may be either a transparent or non-transparent electrode.

According to another aspect of the invention, there is provided a method for depositing nanoparticles on a substrate. The method comprising the steps of: generating an aerosol of micron-sized droplets, each droplet comprising a limited number of carbon nanoparticles; and subjecting the aerosol to an electrostatic field that causes the micron-sized droplets to be deposited on a substrate.

In an embodiment, the method further comprises a step of passing the micron-sized droplets through a mask prior to being deposited on the substrate.

In a further embodiment, the method further comprises maskless patterning of the nanoparticle film on the substrate by patterned charging of the substrate. The electrostatic field may be provided by interspaced charged plates and the substrate positioned on the grounded charged plate. The charged plates may be electrostatically charged insulators or voltage biased conductors. The charged plates can be patterned to spatially modulate the electric field and promote carbon nanotube deposition at specific locations on the substrate.

In a still further embodiment, the aerosol flows in a laminar fashion and is spatially engineered to afford nanoparticle deposition at specific locations on the substrate. The substrate can have a conductive surface or a dielectric surface.

According to another aspect of the invention, there is provided a material that has a hydrophobic surface and at least one nanoparticle adhered on the surface.

In one embodiment, a plurality of nanoparticles is provided in a network. The nanoparticles can act as transistors.

In a further embodiment, the surface has a water contact angle greater than 80° such as poly(vinylphenol) based dielectric or a polytetrafluoroethylene based dielectric, for example Xerox™ Dielectric xdi-d1.2 or Teflon®-AF, or a fluoropolymer, such as the amorphous (non-crystalline) fluoropolymer CyTOP®.

In a still further embodiment, the material is provided as a semiconductor in a thin film transistor. In other embodiments, the material can be a conductive electrode, a diode, a photovoltaic cell, a physical sensor or chemical sensor. The conductive electrode may be either a transparent or non-transparent electrode.

In the inventions described above, the substrate is a conductive surface or a dielectric surface. In one embodiment, the substrate has an at least partially conductive surface. In another embodiment, the substrate has an at least partially dielectric surface. The surface may be a hydrophilic or hydrophobic surface, in some embodiments.

In one embodiment, a hydrophobic surface is used to eliminate the interference of humidity that can confound the sensing of an analyte, for example. In one embodiment, the substrate/material is a device such as, for example, a physical or chemical sensor that is devoid of humidity fluctuations. In one particular embodiment, the apparatus described herein is used in the production of such a substrate/material, which for example, could be a thin film transistor having said substrate/material as a dielectric or as a coating at the interface between a dielectric and a network of SWCNTs. This results in minimal hysteresis due to the elimination of interactions between the SWCNT network and atmospheric water. In such a device or sensor, the hysteresis that could result would be principally from interactions between the SWCNT network and desired analyte. This material can be particularly helpful in minimizing the impact of relative humidity changes on the use of a sensor.

In other embodiments, the substrate has a surface with water contact angle greater than 80°, for example between 85° and 120°, about 90° or between 117-120°.

In other embodiments, the surface may be a modified oxide surface, for example self-assembled monolayers on SiO₂, Al₂O₃, ZrO₂ or HfO₂.

In other embodiments, the surface may be polymeric. Polymers may be homopolymers or copolymers, for example alternating copolymers, periodic copolymers statistical copolymers, block copolymers and the like.

In other embodiments, the polymer may be fluorinated. Some examples of fluorinated polymers include, but are not limited to: fluorinated polyalkenes, fluorinated polyacrylates, fluorinated polymethacrylates, fluorinated polystyrenes, fluorinated polycarbonates, fluorinated silicones and fluorinated poly(p-xylylene) polymers (e.g. Parylene).

Example surfaces, or polymers, include, but are not limited to: polyvinylidene chloride, polyvinylidene fluoride; polyhexamethylene adipamide (Nylon 66); Nylon 7; poly(dodecano-12-lactam) (Nylon 12); polyamide; cellulose acetate; polysulfone; polymethyl methacrylate; polyvinyl acetate; polycarbonate; polystyrene; polypropylene; polyimide; epoxy; polyethylene terephthalate; silicones; olefins (alkenes); cellulose nitrate; ultra-high-molecular-weight polyethylene; polychloroprene; polyvinyl chloride; latex; butyl rubber; polytetrafluoroethylene; and poly(p-xylylene) polymers (e.g. Parylene).

In some embodiments, the hydrophobic surface is a poly(vinylphenol) based dielectric or a polytetrafluoroethylene based dielectric.

In some embodiments, the surface is polymethylsilsesquioxane.

In some embodiments, the surface is polytetrafluoroethene; perfluorovinylpropyl ether-tetrafluoroethylene copolymer; tetrafluoroethene-perfluoro(propylvinylether) copolymer; poly[tetrafluoroethylene-co-perfluoro (alkyl vinyl ether)]; tetrafluoroethylene/perfluoro(propylvinylether) copolymer; polytetrafluoroethylene-perfluoroalkyl vinyl ether copolymer; poly(tetrafluoroethylene-co-tetrafluoro-ethylene perfluoropropyl ether); 1,1,1,2,2,3,3-heptafluoro-3-[(trifluoroethenyl)oxy]-propan polymer with tetrafluoroethene; or 1,1,1,2,2,3,3-heptafluoro-3-[(trifluorovinyl)oxy]propane/tetrafluoroethylene copolymer.

In addition, in the inventions described above, each micron-sized droplet can comprise less than 5 nanoparticles per droplet, for example one nanoparticle per droplet.

Moreover, in the inventions described above, the nanoparticle can be boron nitride, molybdenum disulfide, tungsten disulfide, a carbon- or phosphorus-based nanoparticle. In another embodiment, the nanoparticle can be a combination of the above materials. In each case, the nanoparticle can take on various crystalline forms, such as single-walled or multi-walled nanotubes, nanorods, nanospheres, nanoflakes or nanoribbons. In one embodiment, the nanoparticle is a single-walled carbon nanotube. In another embodiment, the nanoparticle is a graphene nanoribbon.

According to another aspect of the present invention, the apparatus described hereinabove can form part of a roll-to-roll printing system.

According to another aspect of the present invention, there is provided a material comprising polymers having carbon nanotube networks deposited thereon by the apparatus described above for use as gate dielectrics in a bottom gate transistor or as an encapsulation layer.

According to a further aspect of the present invention, there is provided a material comprising polymers having carbon nanotube networks deposited thereon by the apparatus described above for use as gate dielectrics in an air exposed transistor without an encapsulation layer.

In one embodiment, the material has transfer characteristics without hysteresis from 0-1 MV/m applied gate field.

Further features will be described or will become apparent in the course of the following detailed description. It should be understood that each feature described herein may be utilized in any combination with any one or more of the other described features, and that each feature does not necessarily rely on the presence of another feature except where evident to one of skill in the art.

### BRIEF DESCRIPTION OF THE DRAWINGS

These and other features, aspects and advantages of the present invention will become better understood with regard to the following description and accompanying drawings wherein:

FIG. 1 is a schematic of an apparatus according to an embodiment of the present invention;

FIG. 2 is a scanning electron microscopy image of a network of single-walled carbon nanotubes assembled using the apparatus of the present invention;

FIG. 3 is a schematic of the deposition chamber according to an embodiment of the present invention;

FIG. 4 is an optical (top) and scanning electron microscopy (bottom) image showing patterned nanotube networks obtained combining a shadow mask with the apparatus of the present invention;

FIG. 5 is an optical image of a series of depositions performed under different electric field intensities, (a) and (b) being the same image taken under different illumination conditions;

FIG. 6 is a graphical representation of carbon nanotube transistors on polymer dielectrics. Transfer characteristics are shown on linear and logarithmic scales for forward and reverse sweep directions. a) Xerox Dielectric xdi-d1.2. Sweep rate is 0.22 V/s. b) Teflon-AF. Sweep rate 0.55 V/s;

FIG. 7 is a graphical representation of a gate dielectric stress test. a) Transfer characteristics for Xerox Dielectric xdi-d1.2 taken at different sweep ranges from ±10 V to ±60 V. The sweep frequency is 110 mHz. Inset shows extracted threshold voltages (Vₜ) for forward (F) and reverse (R) sweep directions. b) Time evolution of the transistor conductance (red trace) for Xerox Dielectric xdi-d1.2 under a sequence of gate voltages (blue trace). c) Transfer characteristics for Teflon-AF dielectric taken at different sweep ranges from ±15 V to ±75 V. The sweep frequency is 110 mHz. Inset shows extracted threshold voltages (Vₜ) for forward (F) and reverse (R) sweep directions. d) Time evolution of transistor conductance (red trace) for Teflon-AF dielectric under a sequence of gate voltages (blue trace); and

FIG. 8 is a graphical representation of transfer characteristics of encapsulated, bottom gate SWCNT network transistor using Xerox Dielectric xdi-d1.2 both dielectric and encapsulation layers.

FIG. 9 depicts maskless deposition of carbon nanotube films. (a) Deposition from a slit-shape nozzle. (b) Raman intensity profile across a stripe (grey circle) of carbon nanotube material. The light gray line is a lorentzian profile. (c) Deposition pattern obtained from a nozzle with multiple apertures. From left to right, the sample is immobile for two durations and then continuously translated for 3 mm, and then immobile again for two more steps. (d) Deposition of carbon nanotubes on a nylon film using a sample holder with a patterned ground.

FIG. 10 is a schematic of nozzle designs to facilitate both aerosol injection and gas recovery. FIG. 10a illustrates a single coaxial nozzle design. FIG. 10b illustrates a multiple coaxial nozzle design.

### DETAILED DESCRIPTION OF INVENTION

The following description is of illustrative embodiments by way of example only and without limitation to the combination of features necessary for carrying the invention into effect.

Unless defined otherwise, all technical and scientific terms used herein have the same meaning as commonly understood by one of ordinary skill in the art to which this invention belongs. It must also be noted that, as used in the specification and the appended claims, the singular forms “a,” “an” and “the” include plural referents unless the context clearly dictates otherwise.

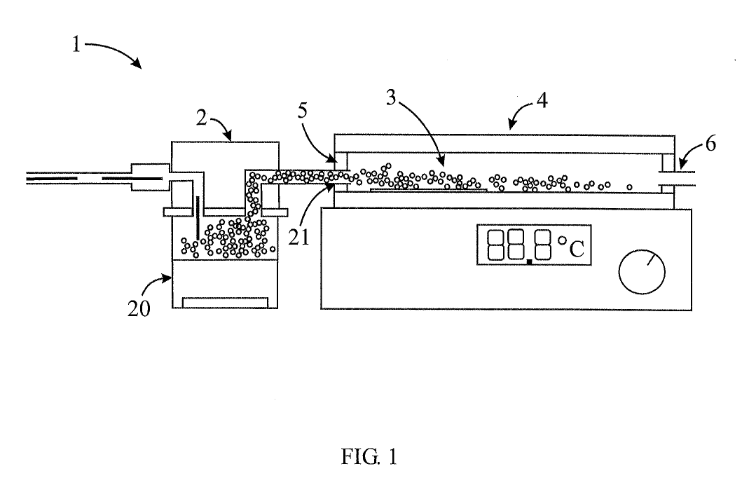

As shown in FIG. 1, the apparatus (1) for deposition of carbon nanotubes on a substrate includes: an aerosol generator (2) for generating an aerosol of micron-sized droplets (3) and a deposition chamber (4) for receiving the droplets from the generator (2). The deposition chamber (4) has an electrostatic field (5) for attracting droplets (3) in the aerosol to a substrate. The electrostatic field (5) being substantially perpendicular to the substrate. In other words, the electrostatic field is more or less 90 degrees to the substrate. The apparatus (1) described herein can form part of a roll-to-roll printing system.

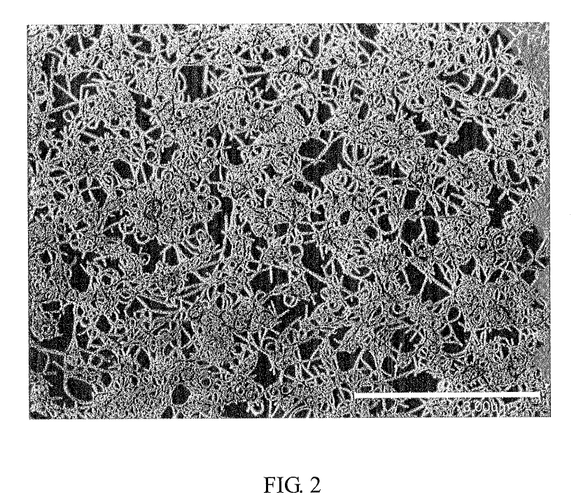

In most cases, the aerosol generator (2) is a separate unit within the apparatus (1). However, the aerosol generator (2) can be integrally connected to the deposition chamber (4). In either case, the aerosol generator (2) is responsible for generating an aerosol of micron-sized droplets (3). The aerosol generator (2) will typically include a mist generating chamber (20) and a nozzle (21). However, it is possible to generate an aerosol by linking a container containing a solution directly to an atomizer nozzle. For example, in order to produce the micron-sized droplets, a high frequency ultrasonic atomizer, is typically used although other types of atomizers, in the form of nozzles, can create atomization from a variety of mechanical means, such as, but not limited to, electrostatic processes and centrifugal forces, may be used. Moreover, aerosol can be generated using a pneumatic aerosol generator or electrospray processes. In one embodiment, each droplet (3) contains a limited number of nanoparticles, for example, five or less nanoparticles. Droplets containing a nanoparticle, such as a single-walled carbon nanotube, are particularly useful in forming electrical networks (FIG. 2).

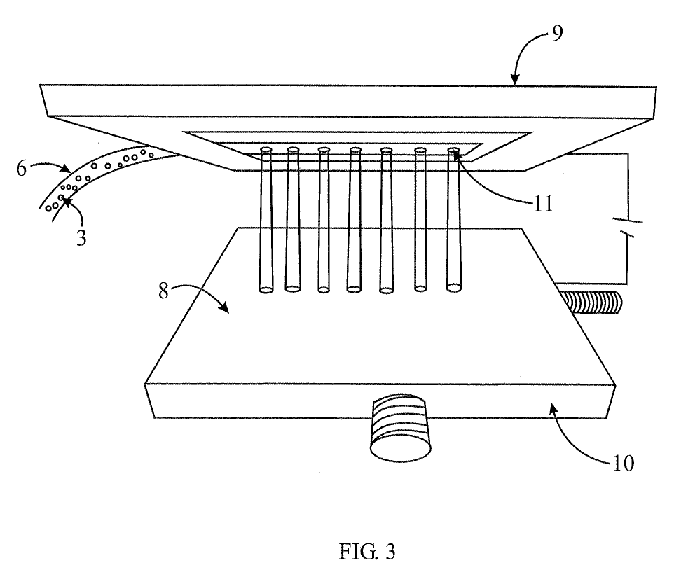

The aerosol of micron-sized droplets (3) is fed into a deposition chamber (4) through an inlet (5) connected to the nozzle (21) or through a conduit (6) connecting the nozzle (21) to the deposition chamber (4). The aerosol travels through the deposition chamber (4), and if not deposited on the substrate, exits the chamber (4) through an outlet (7). As shown in FIG. 3, the droplets (3) are attracted or drawn to the substrate (8) by an electrostatic field created by a charged top plate (9) and grounded bottom plate (10), such as, but not limited to, electrostatically charged insulators or voltage biased conductors. The substrate (8) is positioned on the bottom plate (10) to receive the individual droplets (3) from the aerosol.

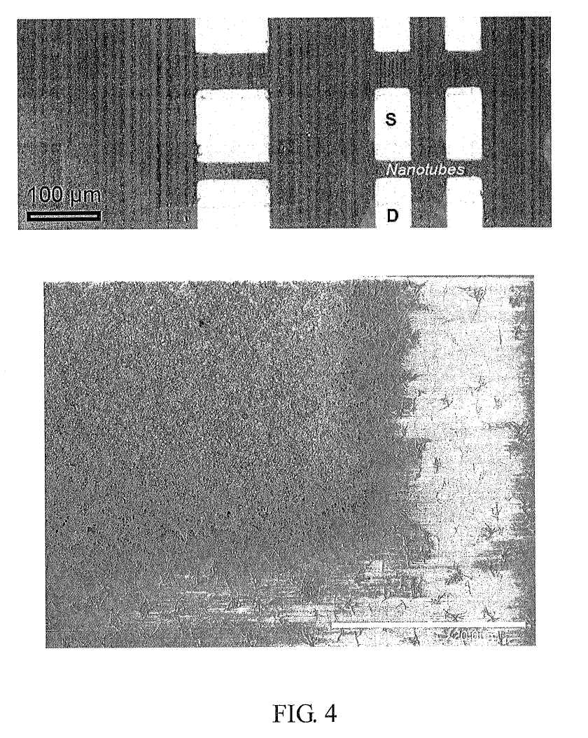

In one embodiment, one or more injector nozzles (11) are provided in conjunction with the charged top plate (9) to introduce the droplets (3) to the electrostatic field created between the charged top plate (9) and the grounded bottom plate (10). In this embodiment, the droplets (3) are propelled through openings in the charged top plate and attracted or drawn to the substrate (8) through the electrostatic field. Optionally a stencil mask can be provided between the flow of the aerosol and the substrate (8). As shown in FIG. 4, use of a stencil mask allows for the deposition of droplets (3) to be patterned on the substrate (8) in a predefined manner.

In another embodiment, the charged top (9) and/or bottom plates (10) are patterned to spatially modulate the electrostatic field in order to promote carbon nanotube deposition at specific locations on the substrate (8). Similarly, the aerosol can flow in a laminar fashion through the deposition chamber (4) and be spatially engineered to afford carbon nanotube deposition at specific locations on the substrate (8).

The precipitation of carbon nanotube particles on the substrate (8) can also be controlled or patterned by adjusting the deposition parameters of the starting solution of the material being deposited or adhered onto the substrate; the aerosol flow rate; the electrostatic field; the nozzle temperature, the substrate temperature and atmospheric content of the deposition chamber; and/or the composition of the carrier gas that flows through the deposition chamber.

The apparatus (1) described herein allows for nanoparticle films/networks, for example, to be patterned on the substrate to sub-millimetre feature sizes. Nanoparticles that either carry a net charge or are charge neutral but have strong electrical polarizability, are particularly useful in the apparatus (1). Charged/polarizable nanoparticles will interact with the electrostatic field in the deposition chamber (4), causing the nanoparticles to be adhered to the substrate (8). The intensity of the interaction with the electrostatic field can be adjusted in two ways: externally, using Corona discharge or UV exposure, for example, to change the charge on the nanoparticle; or intrinsically, by modifying the solution's chemical characteristics.

In some instances, deposition of material using an aerosol system of the present invention may be sensitive to details of the gas flow. Small disruption or asymmetry in the gas flow may reduce uniformity of deposited material. This may be important especially for scaling up deposition to accommodate larger samples, for example samples having an area of greater than about 10 cm². In another embodiment, further improvements to deposition uniformity may be achieved by altering nozzle design to combine both aerosol injection and gas recovery.

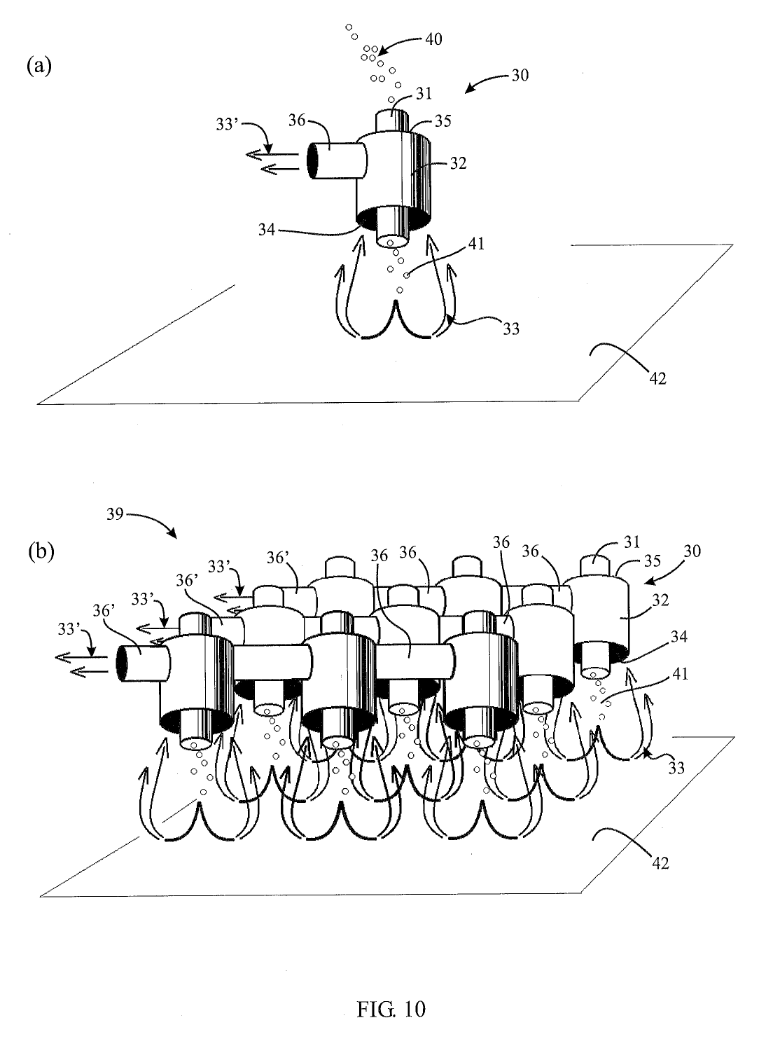

FIG. 10 illustrates two nozzle designs to facilitate both aerosol injection and gas recovery. FIG. 10a illustrates a single coaxial nozzle design, while FIG. 10b illustrates a multiple coaxial nozzle design. Referring to FIG. 10a, a coaxial nozzle (30) comprises an aerosol feed conduit (31) axially aligned with an electrostatic field to permit injection of an aerosol (40) into a deposition chamber so that droplets (41), only one labeled, are propelled toward a substrate (42). The coaxial nozzle (30) further comprises a gas return conduit (32) housing the aerosol feed conduit (31). In the embodiment shown, the aerosol feed conduit (31) preferably extends through and is preferably concentric with the gas return conduit (32). However, other arrangements in which an aerosol feed conduit is housed inside a gas return conduit are suitable. The diameter of the gas return conduit (32) is larger than the diameter of the aerosol feed conduit (31) by an amount sufficient to permit reentry gases (33), for example carrier gas and solvent gas, to re-enter the nozzle (30) in a space (34) outside the aerosol feed conduit (31) and inside the gas return conduit (32). Back pressure in the deposition chamber facilitates reentry of the gases (33) into the nozzle (30). An end (35) of the gas return conduit (32) may be sealed around the aerosol feed conduit (31) to force reentry gases (33) into an exhaust outlet (36) in fluid communication with and extending transversely from the gas return conduit (32), preferably proximate the end (35) of the gas return conduit (32). The reentry gases (33) are expelled through the exhaust outlet (36) as exhaust gases (33′).

Referring to FIG. 10b, the multiple coaxial nozzle design comprises a plurality (39) of single coaxial nozzles (30), only one labeled, as described in FIG. 10a. The plurality (39) of single coaxial nozzles (30) are fluidly interconnected through exhaust outlets (36), only a few labeled, of each nozzle (30) so that reentry gases (33) are collected and exhausted as exhaust gases (33′) out of the plurality (39) of nozzles (30) through terminal exhaust outlets (36′). While FIG. 10b illustrates three rows of nozzles (30), each row separately exhausting exhaust gases (33′) through three terminal exhaust outlets (36′), any suitable arrangement of nozzles (30) and connection of exhaust outlets (36) may be used.

Examples of nanoparticles that can be used in the apparatus (1) include, but are not limited to, boron nitride, molybdenum disulfide, tungsten disulfide, and phosphorus- or carbon-based nanoparticles. Nanoparticles may comprise other elements that alter electronic properties, for example carbon nanotubes may comprise boron, nitrogen or other elements to alter electronic properties of the carbon nanotubes. Depending on the application, any one of the crystalline forms of these compounds could be used. For example, carbon-based nanoparticles could include carbon nanotubes, nanorods, nanospheres, nanoflakes and nanoribbons. Single-walled carbon nanotubes are particularly useful for high performance printed transistors. Graphene nanoribbons are also particularly useful as semiconductors in transistors. Further examples of nanoparticles, can include polymers having a molecular weight between about 1,000 and 1,000,000 g/mol. Other examples of nanoparticles that can be used in the apparatus (1) can be a combination of the above materials. The substrate (8) used in the apparatus is chosen based on the product being manufactured. In most cases, the substrate will be an electrically insulating material, such as, a hydrophilic or hydrophobic dielectric surface, that when coated with a network of single-walled carbon nanotubes can function as a thin (or ultra thin) film transistor. However, other applications may require the use of a conductive substrate, such as metal, having nanoparticles adhered thereto. The substrate will often be patterned with multiple materials typical of printed devices, for example dry/cured conductive, insulating and dielectric inks. The manufactured product can be a diode, a conductive electrode (transparent or non-transparent), a photovoltaic cell, a physical sensor, a chemical sensor or all possible combinations of such devices.

The nanoparticles have a size that should not exceed the size of the droplet. For droplets having a diameter of about 1000 nm, a longest dimension of the nanoparticles may be in a range of about 100-1000 nm. For nanoflakes, diameters may be in a range of about 50-1000 nm. The nanoparticles may be 2-dimensional or 3-dimensional.

The invention is not limited to any particular solvent. Some examples of solvents that can be aerosolized include, but are not limited to non-polar solvents (e.g. toluene, chlorobenzene, and the like) and polar solvents (e.g. alcohols, ketones, water, and the like). Non-polar solvents are generally preferred.

Aerosol properties may be suitably adjusted to optimize performance. Diameter of solvent droplets in the aerosol is preferably in a range of about 0.5 to 5 μm. Droplet concentration in the gas stream is preferably less than 10%, for example less than about 1%. Droplet velocity is preferably less than about 10 cm/s. Deposition time is preferably in a range of a few seconds to several minutes, for example about 2 seconds to 5 minutes. In a continuous deposition process, where deposition rates are more appropriate measure, deposition rate is preferably in a range of about 1 to 100 nanotubes per second per micron squared.

Nozzle design may be suitably adjusted to optimize performance. Preferably, nozzle apertures have a minimum dimension greater than about 10× the diameter of the droplet, for example the minimum dimension may be about 10 micron or more. Preferably, nozzle apertures have a minimum dimension determined by the distance to the substrate. For a 1-10 mm gap, apertures preferably do not exceed about 0.5-5 mm, respectively, in order to maintain deposition uniformity. Nozzle shape is not particularly limited. For example, nozzle shape can be simple in “pixelated” deposition (single hole or slit opening), or complex if a pattern is achieved with a single nozzle (e.g. using a shadow mask as nozzle). Nozzles are preferably designed so that gas recovery does perturb flow pattern of the aerosol.

Carrier gases for the aerosol are preferably inert to the solvent, nanoparticles and/or the atmosphere. Some non-limiting examples of carrier gases include N₂, Ar, He and vapors of solvents to control droplet drying and film morphology.

Electrostatic field intensity is preferably greater than about 100 kV/m, for example about 1 MV/m. Both charged and polarizable nanoparticles may be utilized, and especially with polarizable nanoparticles, it may be useful to also adjust field gradient to optimize deposition of the nanoparticles. Nanoparticles may be charged by the electrostatic field during deposition.

In one particularly interesting embodiment, the substrate is a surface or polymer with water contact angle greater than 80°. Such primarily hydrophobic surfaces typically have water contact angles between 85-120°, with particularly useful surfaces having contact angles around 90°+/−5° or between 117-120°. Examples of such surfaces, or polymers, include, but are not limited to: polyvinylidene chloride and polyvinylidene fluoride; polyhexamethylene adipamide (Nylon 66); Nylon 7; poly(dodecano-12-lactam) (Nylon 12); polyamide; cellulose acetate; polysulfone; polymethyl methacrylate; polyvinyl acetate; polycarbonate; polystyrene; polypropylene; polyimide; epoxy; polyethylene terephthalate; silicones; olefins (alkenes); cellulose nitrate; ultrahigh-molecular-weight polyethylene; polychloroprene; polyvinyl chloride; latex; butyl rubber; polytetrafluoroethylene; and poly(p-xylylene) polymers (e.g. Parylene). In some embodiments, the hydrophobic surface is a poly(vinylphenol) based dielectric or a polytetrafluoroethylene based dielectric. A non-limiting example of a poly(vinylphenol) based dielectric would be Xerox™ Dielectric xdi-d1.2 (supplied by the Xerox Research Centre of Canada), whereas an example of polytetrafluoroethylene based dielectric includes: Teflon®-AF. In other embodiments, the hydrophobic surface is a fluoropolymer, such as the amorphous (non-crystalline) fluoropolymer CyTOP®. Such polymers having carbon nanotube networks deposited thereon by the apparatus described above, can be used as gate dielectrics in a bottom gate transistor or as an encapsulation layer. In air exposed transistors without an encapsulation layer, the transfer characteristics of the material indicate little to no hysteresis (i.e. from 0-1 MV/m, which corresponds to 0-1 V for a 500 nm dielectric with a dielectric constant of 2). These examples demonstrate the value of electrostatically assisted aerosol deposition to overcome the fabrication challenges present especially in hydrophobic polymer dielectrics. Results indicate that such transistors printed on these substrates are very robust and can meet some of the performance metrics required for the fabrication of commercial products.

### EXAMPLES

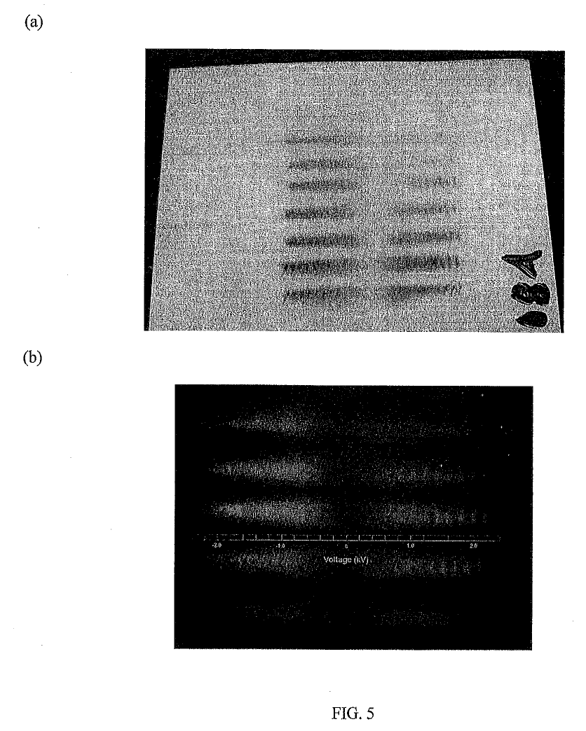

The effect of modifying the intensity of the electric field in the deposition chamber on the deposition of carbon nanotubes on the substrate was examined. As shown in FIG. 5, seven injector nozzles were used to deposit single-walled carbon nanotubes on a silicon substrate. The seven injector nozzles gave rise to the seven horizontal deposition patterns shown in the top section of FIG. 5a. From right to left, the applied voltage varied from +2400 V to −2400 V in steps of 200 V, which corresponds to 25 different conditions. Between each voltage, the sample was translated 600 μm in the horizontal direction. At the highest fields, isolated dark stripes were clearly visible, with lateral dimensions below 100×600 μm². As the field weakens, the deposition pattern spreads until the laminar flow from neighboring nozzles prevents further spreading. This is clearer in FIG. 5b which was taken under different illumination conditions. It should be noted that when the field is absent (vertical middle section), little material is deposited.

Aerosol deposition appears to be much less sensitive to surface energy where poor carbon nanotube adherence is found using other deposition methods. For Xerox Dielectric xdi-d1.2 (supplied by the Xerox Research Centre of Canada), networks formed readily on polymer layers obtained from spin coating, without surface treatment. The Xerox Dielectric comprises a dielectric material and a low surface tension additive (see U.S. Pat. No. 8,821,962, the contents of which is herein incorporated by reference). The low surface tension additive enables the formation of a thin, smooth dielectric layer with fewer pinholes and enhanced device yield. The dielectric material comprises a high-k dielectric, Poly(4-vinylphenol) (PVP) and a low-k dielectric, Poly(methyl silsesquioxane) (pMSSQ). Direct comparisons were made with networks on SiO₂ and, except for the hysteresis being larger on SiO₂, electrical data were similar in many respects (nominal mobility and current On/Off ratio). In the case of Teflon-AF, a 15 minute UV-Ozone exposure (conditions were not optimized) was used to promote carbon nanotube adhesion. The treatment led to minimal change of the water contact angle from 120° to 117° (a direct measure of hydrophobicity). For both Xerox Dielectric xdi-d1.2 and Teflon-AF, carbon nanotube adhesion was sufficiently strong for the rinsing steps required to remove excess dispersant in the nanotube ink formulation.

TABLE 1
Polymer dielectric physical parameters

| | | Dielectric | Contact | Thickness |
|---|---|---|---|---|
| | Material | Constant | Angle | (nm) |
| Xerox | Poly(vinylphenol)/ | 4.0 | 89° | 530 |
| Dielectric | Poly(methylsilsesqui- | | | |
| xdi-d1.2 | oxane) Blend | | | |
| Teflon ®-AF | Poly(perfluorodioxole- | 1.9 | 120° | 480 |
| 2400 X SOL | co-tetrafluoroethylene) | | (117°) | |

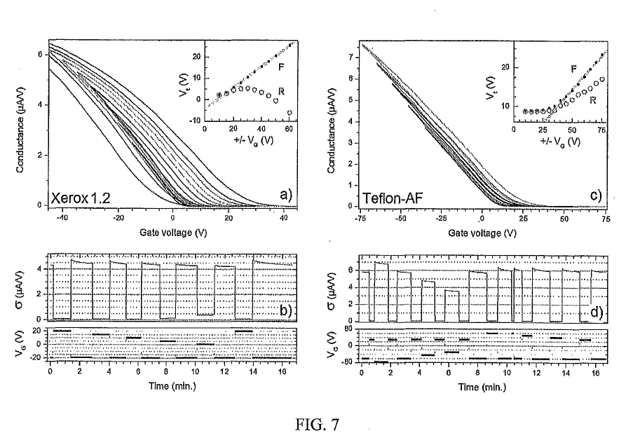

TABLE 2
Transistor performance parameters from FIG. 7

| | Mobility | Threshold | |
|---|---|---|---|
| | (cm²/Vs) | Voltage (V) | Hysteresis (V) |
| Xerox Dielectric | 6.5 | 4.15 | 0.004 ± 0.030 |
| xdi-d1.2 | | | |
| Teflon ®-AF | 4.1 | 10.5 | 0.45 ± 0.02 |

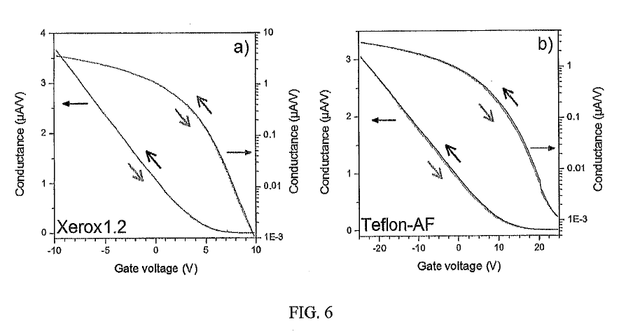

Transistors fabricated with Xerox Dielectric xdi-d1.2 and Teflon-AF dielectrics were found to have good performance metrics in terms of hole mobility, On-current and Off-current. Transistor transfer characteristics (source-drain conductance versus gate voltage) are shown in FIG. 6 and Table 2 summarizes performance numbers obtained from data analysis. In striking contrast with devices on SiO₂/Si surfaces under similar measurement conditions (and dielectric thicknesses), the magnitude of the hysteresis between forward and reverse gate sweeps are small for both dielectrics. In the case of Xerox Dielectric xdi-d1.2 (FIG. 6a), the hysteresis is essentially absent (0.004±0.030 V) with forward and reverse sweeps tracking perfectly on both linear and logarithmic scales. For Teflon-AF (FIG. 6b), the hysteresis is also very small with a value of 0.45±0.02 V.

In order to further assess the dielectric quality of the polymers, two sets of “stress test” measurements were performed. When transistor devices are stressed, large voltages are applied to the gate or source-drain electrode, and electrical data is acquired dynamically. Those results are shown in FIG. 7. In FIG. 7 a) and c), transfer curves are obtained at progressively greater gate voltage sweep ranges. In both cases, a hysteresis eventually develops together with a shift of threshold voltage (Vₜ). The inset in FIG. 7 a) and c) displays Vₜ for forward (F) and reverse (R) sweep direction. For Xerox Dielectric xdi-d1.2, a 1 V hysteresis is found for V_{G}=±20 V range and grows to >30 V for V_{G}=±60 V. The opening of the hysteresis is asymmetric, growing first on the forward sweep (turn off) while the reverse sweep starts opening significantly only beyond V_{G}=−35 V. These results indicate both donor and acceptor trap charges are contributing to the hysteresis. The linear dependence of Vₜ vs±V_{G} suggests a simple energy distribution of charge traps. PVP based dielectrics have yielded good electrical performance in organic TFTs, and crosslinking chemistry has been shown to dramatically impact TFT performance, yet the use of PVP in SWCNT TFTs is scarcely reported, with no mention on the magnitude of hysteresis. Inadequately cross-linked PVP contains a significant number of hydroxyl groups which exacerbates the redox reaction for devices exposed to air ambient, thus leading to large hysteresis (similar to SiO₂). In fact, it has been noted that PVP is inherently hygroscopic and in the context of SWCNT based devices, and the redox chemistry that can occur, a hydrophobic formulation as described herein is clearly advantageous. The large contact angle measured on Xerox xdi-d1.2 is attributed to the migration of poly(methyl silsesquioxane) to the surface of the PVP dielectric. Pure poly(vinyl phenol), with a large number of hydroxyl groups at the surface would show strong hydrophilicity.

Similar to Xerox Dielectric xdi-d1.2, increase in the gate voltage range in Teflon-AF devices (FIG. 7c) leads to a gradual appearance of a hysteresis. The magnitude however is smaller and is only 5 V for the V_{G}=±75 V sweep range (Teflon-AF has a low dielectric constant, κ=1.9, and direct comparison with Xerox Dielectric xdi-d1.2 can be made using electric polarization field P=V/κd, where d is the film thickness). A gradual shift of Vₜ to more positive V_{G}, from Vₜ=7 V to 20 V was noted. The asymmetry found between F and R sweep directions in the case of Xerox Dielectric xdi-d1.2 is not seen for Teflon-AF. Teflon-AF is an amorphous fluoropolymer having highly electronegative fluorine atoms. This attribute results in efficient electron withdrawing from the carbon nanotube and easy electron trapping at the Teflon surface. For holes however, a deep HOMO level would prevent significant bias stress for negative gate voltages.

The second “stress test” consisted of measuring the time evolution of conductance while the transistor is being subsequently switched between its “On” and “Off” state. For Xerox Dielectric xdi-d1.2, V_{G} within the ±20 V range was looked at where the hysteresis remained quite small. The time evolution in FIG. 7b displays six consecutive switch-Offs where V_{G} takes different values from 0 to 20 V, corresponding to various degrees of stress in the Off state. Here, the effect of V_{G}>0 was studied since that's where the hysteresis growth is most pronounced (asymmetry in FIG. 4a and inset). In all cases, when the transistor is switched-On at V_{G}=−20 V, a transient is seen in the conductance on the timescale of seconds. The magnitude of the overshoot is larger for larger Off-state gate voltage, which is consistent with a bigger applied stress. The conductance recovers within 10% of the average value of 4.3 μA/V demonstrating good dielectric robustness.

In FIG. 7d, a similar test on transistors was performed made with Teflon-AF. A sequence of ten Off-states is presented with both On and Off values of the gate voltages being varied. In the first five cycles, a constant Off-state V_{G}=30 V is applied with different On-state V_{G}. The On-state shows a conductance overshoot with a few percent decay for the largest stress applied (V_{G}=−75 V). The transient occurs on a timescale of seconds. In the sequence that follows, a constant On-state V_{G}=−60 V with different degrees of Off-State bias stresses (similar to FIG. 7b) are applied. A short transient was also found here with the largest magnitude seen for the larger bias stress. In all cases, the conductance settles to within 2% of the average conductance of 6 μA/V.

Two performance requirements for applications in electronics are met when SWCNT networks are assembled on top of hydrophobic polymer dielectrics: the absence of hysteresis and time stability, particularly in the device's On-state. The absence of hysteresis and the robustness to stress tests indicate first that the polymers, the major component of the formulation, perform well as dielectrics, with a low level of dynamic charge traps. This is expected considering they are formulated for use as dielectrics in electronics applications, but it should be noted that many publications using PVP as a dielectric do not provide the same performance attributes that were observed with the Xerox Dielectric xdi-d1.2 formulation. The crosslinking chemistry and the layering property of the polymer blend have a significant effect on device performance and is a good match with semiconducting-SWCNT as the semiconducting channel. These results should serve as a guide to obtain robust bottom gate devices using normal processing in air ambient and Xerox Dielectric xdi-d1.2 represents a practical route to using established printing techniques and simple processes (conventional solvents).

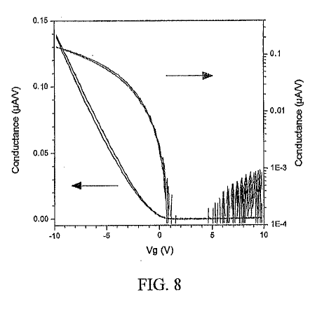

Encapsulation of transistors with Xerox Dielectric xdi-d1.2 produces the desired shift in threshold voltage. FIG. 8 shows a transfer characteristic with Vₜ near 0 V. Although the On/Off ratio measured at 0 V is poor (<4) for un-encapsulated devices in air ambient, it improves to 10² after encapsulation.

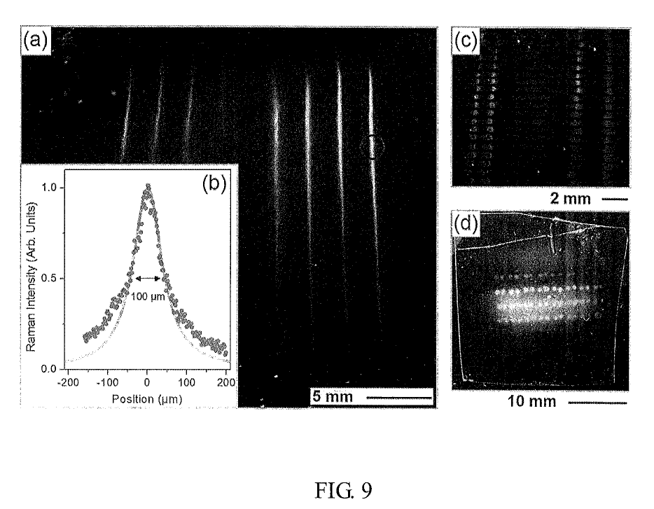

Aerosol processes of the present invention are compatible with shadow masking. Although mask fabrication can prove useful, it is technologically more desirable to have a process capable of producing patterns in a maskless fashion. FIG. 9 shows three examples of how this is possible by engineering both the gas flow and the electrostatic field.

FIG. 9a demonstrates how tightly the electrostatic field can focus the material. Optically, it can be seen that the stripes deposited at the highest voltages appear very sharp with dimensions well under a millimeter. FIG. 9b presents a Raman intensity profile taken across a stripe and reveals a FWHM (Full-width at half-maximum) of 100 μm. Even with the overspread of material beyond 200 μm, transistors with channel width below 150 μm can be fabricated using a simple slit-shape nozzle. Patterning in the transverse direction can also be achieved by using a nozzle comprising multiple holes. An example of such a deposition is shown in FIG. 4c. Individual islands of material as well as lines can be obtained with dimensions of order 500 μm. Here, in addition to the focusing action of the electrostatic field, the absence of flow mixing inherent to the laminar regime prevents material from depositing in areas between the holes. Improvements in nozzle design and flow engineering should allow feature sizes of 100 μm or less in both lateral and transverse directions.

A very appealing perspective for maskless patterning is through electric field engineering. In the previous examples, the electric field remained minimally patterned. However, we could attribute the focusing of material to the nozzle curvature and/or to apertures (slit or holes). Going beyond the nozzle, upon patterning the ground electrodes, deposition of nanotubes may occur at specific locations. FIG. 9d shows one example of carbon nanotube islands deposited on a thin nylon film. The mask is a Teflon™ slab with copper wire inclusions connected to ground. Even if this experiment used a slit-shape nozzle with uniform delivery of droplets, deposition occurred mainly over the copper areas. This is a simple consequence of the higher field (and/or field gradient) in those areas compared to Teflon™ where the ground is (spatially) approximately 2 mm lower.

It will be understood that numerous modifications thereto will appear to those skilled in the art. Accordingly, the above description and accompanying drawings should be taken as illustrative of the invention and not in a limiting sense. It will further be understood that it is intended to cover any variations, uses, or adaptations of the invention following, in general, the principles of the invention and including such departures from the present disclosure as come within known or customary practice within the art to which the invention pertains and as may be applied to the essential features herein before set forth, and as follows in the scope of the appended claims.

We claim:

1. An apparatus for deposition of nanoparticles on a substrate, said apparatus comprising:
an aerosol generator for generating an aerosol of micron-sized droplets, each droplet comprising a limited number of nanoparticles; and
a deposition chamber for receiving the micron-sized droplets from the aerosol generator, said deposition chamber comprising:
an electrostatic field for attracting droplets in the aerosol to the substrate, wherein
the electrostatic field is substantially perpendicular to the substrate.

2. The apparatus of claim 1, further comprising an injector nozzle with one to several openings either parallel or perpendicular to the deposition substrate.

3. The apparatus of claim 1 or 2, wherein the deposition chamber further comprises a stencil mask positioned between the flow of the aerosol and the substrate.

4. The apparatus of any one of claims 1 to 3, wherein each micron-sized droplet comprises less than 5 nanoparticles per droplet.

5. The apparatus of claim 4, wherein each micron-sized droplet comprises one nanoparticle per droplet.

6. The apparatus of any one of claims 1 to 5, wherein the electrostatic field is provided by interspaced charged plates and the substrate is positioned on the grounded plate.

7. The apparatus of claim 6, wherein the charged plates are electrostatically charged insulators or voltage biased conductors.

8. The apparatus of claim 6, wherein the charged plates are patterned to spatially modulate the electric field and promote nanoparticle deposition at specific locations on the substrate.

9. The apparatus of claim 1, wherein the aerosol flows in a laminar fashion and is spatially engineered to afford nanoparticle deposition at specific locations on the substrate.

10. The apparatus of any one of claims 1 to 9, wherein the substrate has an at least partially conductive surface.

11. The apparatus of any one of claims 1 to 9, wherein the substrate has an at least partially dielectric surface.

12. The apparatus of claim 10 or 11, wherein the substrate has a hydrophilic or hydrophobic surface.

13. The apparatus of claim 10 or 11, wherein the substrate has a surface with water contact angle greater than or equal to 80°.

14. The apparatus of claim 13, wherein the water contact angle is between 85°-120°.

15. The apparatus of claim 14, wherein the water contact angle is about 90°.

16. The apparatus of claim 14, wherein the water contact angle is between 117° to 120°.

17. The apparatus of claim 13, wherein the surface is a fluorinated polymer.

18. The apparatus of claim 13, wherein the surface is selected from the group consisting of: polyvinylidene chloride, polyvinylidene fluoride; polyhexamethylene adipamide (Nylon 66); Nylon 7; poly(dodecano-12-lactam) (Nylon 12); polyamide; cellulose acetate; polysulfone; polymethyl methacrylate; polyvinyl acetate; polycarbonate; polystyrene; polypropylene; polyimide; epoxy; polyethylene terephthalate; silicones; olefins (alkenes); cellulose nitrate; ultra-high-molecular weight polyethylene; polychloroprene; polyvinyl chloride; latex; butyl rubber; polytetrafluoroethylene and poly(p-xylylene).

19. The apparatus of claim 13, wherein the surface is a poly(4-vinylphenol) based dielectric or a polytetrafluoroethylene based dielectric.

20. The apparatus of claim 13, wherein the surface is polymethylsilsesquioxane.

21. The apparatus of claim 13, wherein the surface is: polytetrafluoroethene; perfluorovinylpropyl ether-tetrafluoroethylene copolymer; tetrafluoroethene-perfluoro(propylvinylether) copolymer; poly[tetrafluoroethylene-co-perfluoro (alkyl vinyl ether)]; tetrafluoroethylene/perfluoro(propylvinylether) copolymer; polytetrafluoroethylene-perfluoroalkyl vinyl ether copolymer; poly(tetrafluoroethylene-co-tetrafluoro-ethylene perfluoropropyl ether); 1,1,1,2,2,3,3-heptafluoro-3-[(trifluoroethenyl)oxy]-propan polymer with tetrafluoroethene;1,1,1,2,2,3,3-heptafluoro-3-[(trifluorovinyl)oxy]propane/tetrafluoroethylene copolymer or fluorinated poly(p-xylylene).

22. The apparatus of any one of claims 1 to 21, wherein the nanoparticle is boron nitride, molybdenum disulfide, tungsten disulfide, a carbon- or phosphorus-based nanoparticle.

23. The apparatus of claim 22, wherein the carbon-based nanoparticle is a nanotube, nanorod, nanosphere, nanoflake or nanoribbon.

24. The apparatus of any one of claims 1 to 21, wherein the nanoparticle is a single-walled carbon nanotube.

25. Use of the apparatus of any one of claims 1 to 24 in the production of a thin film of nanoparticles.

26. The use of claim 25, wherein a thin film transistor is produced.

27. Use of the apparatus of any one of claims 1 to 24 in the production of a diode, a conductive electrode, photovoltaic cell, a physical sensor or a chemical sensor.

28. The use of claim 27, wherein the conductive electrode is a transparent or non-transparent electrode.

29. A method for depositing nanoparticles on a substrate, the method comprising the steps of:
generating an aerosol of micron-sized droplets, each droplet comprising a limited number of nanoparticles; and
subjecting the aerosol to an electrostatic field that causes the micron-sized droplets to be deposited on a substrate.

30. The method of claim 29, further comprising the step of passing the micron-sized droplets through a mask prior to being deposited on the substrate.

31. The method of claim 29 or 30, wherein each micron-sized droplet comprises less than 5 nanoparticles per droplet.

32. The method of claim 31, wherein each micron-sized liquid droplet comprises a single nanoparticle.

33. The method of any one of claims 29 to 31, wherein the electrostatic field is provided by interspaced charged plates and the substrate is positioned on the grounded charged plate.

34. The method of claim 33, wherein the charged plates are electrostatically charged insulators or voltage biased conductors.

35. The method of claim 33, wherein the charged plates are patterned to spatially modulate the electric field and promote nanoparticle deposition at specific locations on the substrate.

36. The method of claim 29, wherein the aerosol flows in a laminar fashion and is spatially engineered to afford nanoparticle deposition at specific locations on the substrate.

37. The method of any one of claims 29 to 36, wherein the substrate has an at least partially conductive surface.

38. The method of any one of claims 29 to 36, wherein the substrate has an at least partially dielectric surface.

39. The method of claim 37 or 38, wherein the substrate has a hydrophilic or hydrophobic surface.

40. The method of claim 39, wherein the substrate has a surface with water contact angle greater than or equal to 80°.

41. The method of claim 40, wherein the water contact angle is between 85°-120°.

42. The method of claim 41, wherein the water contact angle is about 90°.

43. The method of claim 41, wherein the water contact angle is between 117° to 120°.

44. The apparatus of claim 40, wherein the surface is a fluorinated polymer.

45. The method of claim 40, wherein the surface is selected from the group consisting of: polyvinylidene chloride; polyvinylidne fluoride; polyhexamethylene adipamide (Nylon 66); Nylon 7; poly(dodecano-12-lactam) (Nylon 12); polyamide; cellulose acetate; polysulfone; polymethyl methacrylate; polyvinyl acetate; polycarbonate; polystyrene; polypropylene; polyimide; epoxy; polyethylene terephthalate; silicones; olefins (alkenes); cellulose nitrate; ultra-high-molecular weight polyethylene; polychloroprene; polyvinyl chloride; latex; butyl rubber; polytetrafluoroethylene; and poly(p-xylylene).

46. The method of claim 40, wherein the hydrophobic surface is a poly(4-vinylphenol) based dielectric or a polytetrafluoroethylene based dielectric.

47. The apparatus of claim 40, wherein the surface is polymethylsilsesquioxane.

48. The apparatus of claim 40, wherein the surface is: polytetrafluoroethene; perfluorovinylpropyl ether-tetrafluoroethylene copolymer; tetrafluoroethene-perfluoro(propylvinylether) copolymer; poly[tetrafluoroethylene-co-perfluoro (alkyl vinyl ether)]; tetrafluoroethylene/perfluoro(propylvinylether) copolymer; polytetrafluoroethylene-perfluoroalkyl vinyl ether copolymer; poly(tetrafluoroethylene-co-tetrafluoro-ethylene perfluoropropyl ether); 1,1,1,2,2,3,3-heptafluoro-3-[(trifluoroethenyl)oxy]-propan polymer with tetrafluoroethene; 1,1,1,2,2,3,3-heptafluoro-3-[(trifluorovinyl)oxy]propane/tetrafluoroethylene copolymer; or fluorinated poly(p-xylylene).

49. The method of any one of claims 29 to 48, wherein the nanoparticle is boron nitride, molybdenum disulfide, tungsten disulfide, a carbon- or phosphorus-based nanoparticle.

50. The method of claim 49, wherein the carbon-based nanoparticle is a nanotube, nanorod, nanosphere, nanoflake, or nanoribbon.

51. The method of any one of claims 29 to 48, wherein the nanoparticle is a single-walled carbon nanotube.

52. A material comprising a surface with a water contact angle of greater than or equal to 80° and at least one nanoparticle adhered onto the surface.

53. The material of claim 52, wherein the water contact angle is between 85°-120°.

54. The material of claim 53, wherein the water contact angle is about 90°.

55. The material of claim 53, wherein the water contact angle is between 117° to 120°.

56. The material of any one of claims 52 to 55, wherein the nanoparticle is boron nitride, molybdenum disulfide, tungsten disulfide, a carbon- or phosphorus-based nanoparticle.

57. The material of claim 56, wherein the carbon-based nanoparticle is a nanotube, nanorod, nanosphere, nanoflake, or nanoribbon.

58. The material of any one of claims 52 to 55, wherein the nanoparticle is a single-walled carbon nanotube.

59. The material of claim 52, wherein a plurality of carbon nanotubes are provided in a network.

60. The material of claim 59, wherein the carbon nanotube network is the channel of a transistor.

61. The material of claim 59 or 60, wherein the carbon nanotubes are single-walled carbon nanotubes.

62. The material of claim 52, wherein the surface is selected from the group consisting of: polyvinylidene chloride; polyvinylidene fluoride; polyhexamethylene adipamide (Nylon 66); Nylon 7; poly(dodecano-12-lactam) (Nylon 12); polyamide; cellulose acetate; polysulfone; polymethyl methacrylate; polyvinyl acetate; polycarbonate; polystyrene; polypropylene; polyimide; epoxy; polyethylene terephthalate; silicones; olefins (alkenes); cellulose nitrate; ultra-high-molecular weight polyethylene; polychloroprene; polyvinyl chloride; latex; butyl rubber; polytetrafluoroethylene and and poly(p-xylylene).

63. The material of any one of claims 52 to 61, wherein the surface is a poly(4-vinylphenol) based dielectric or a polytetrafluoroethylene based dielectric.

64. The material of claim 63, wherein the poly(4-vinylphenol) based dielectric is Xerox™ Dielectric xdi-d1.2.

65. The material of claim 63, wherein the polytetrafluoroethylene based dielectric is Teflon®-AF

66. The material of any one of claims 52 to 61, wherein the surface is a fluoropolymer.

67. The material of claim 66, wherein the fluoropolymer is the amorphous (non-crystalline) fluoropolymer CyTOP.

68. The material of any one of claims 52 to 67 for use in a thin film of nanotubes.

69. The material of claim 68, wherein the thin film of nanotubes is a semiconductor channel in a thin film transistor.

70. The material of any one of claims 52 to 69 for use in a diode, a conductive electrode, photovoltaic cell, a physical sensor or a chemical sensor.

71. The material of claim 70, wherein the conductive electrode is a transparent or nontransparent electrode.

72. A roll-to-roll printing system comprising the apparatus of any one of claims 1 to 24.

73. A material comprising polymers having carbon nanotubes deposited thereon by the apparatus of any one of claims 1 to 24 for use as gate dielectrics in a bottom gate transistor.

74. A material comprising polymers and carbon nanotubes, wherein the polymers and carbon nanotubes are deposited on a substrate by the apparatus of any one of claims 1 to 24, and wherein the carbon nanotubes are positioned on the polymers for use as a dielectric in a bottom gate transistor.

75. The material of claim 74, wherein the polymers are positioned on the carbon nanotubes for use as a dielectric in a top gate transistor or as an encapsulation layer.

76. The material of any one of claims 73 to 75, wherein the polymers and carbon nanotube networks are simultaneously deposited on the substrate by the apparatus of any one of claims 1 to 24.

77. A material comprising polymers having carbon nanotube networks deposited thereon by the apparatus of any one of claims 1 to 24 for use as gate dielectrics in an air exposed transistor without an encapsulation layer.

78. The material of claim 74, wherein the material has transfer characteristics without hysteresis from 0-1 MV/m applied gate field.
